(19) United States
(12) Patent Application Publication
(10) Pub. No.: US 2026/0150745 A1
(43) Pub. Date: May 28, 2026

(54) COAXIAL WIRE ASSEMBLIES FOR SEMICONDUCTOR PACKAGES

(71) Applicant: Sandisk Technologies, Inc., Milpitas, CA (US)

(72) Inventors: ABHISHEKH M L, BENGALURU (IN); VIJAY KUMAR SINGH, BENGALURU (IN); TAMILHARASAN M, DHARMAPURI (IN)

(21) Appl. No.: 18/956,526

(22) Filed: Nov. 22, 2024

(51) Int. Cl. H01L 23/00

(52) U.S. Cl. CPC H10W 72/50; H10W 72/523; H10W 72/552; H10W 72/5522; H10W 72/5524; H10W 72/5525; H10W 72/553; H10W 72/555; H10W 90/754

(57) ABSTRACT

A semiconductor package includes a substrate, a contact pad formed on the substrate, and a ground pad formed on the substrate, adjacent the contact pad. The semiconductor package also includes a die mounted on the substrate, adjacent the contact pad. The die includes a top surface, and a die contact pad formed on the top surface. Additionally, the semiconductor package includes a coaxial wire assembly extending between the contact pad and the die contact pad of the die. The coaxial wire assembly includes a bond wire contacting and extending between the contact pad and the die contact pad. a dielectric material surrounds the bond wire and a ground material surrounds the dielectric material.

### BACKGROUND

Technological advancements and rapid growth of miniaturized circuits, including system-on-chip devices, memory devices, and so on, have caused bond wires to become an essential element of electronic assemblies. Typically, bond wires are used for making interconnections between integrated circuits (ICs) and other electronic components. Generally, bond wires are made of materials that have a low resistance and good electrical and thermal conductivity. These bond wires, typically bare, uncoated and/or formed from a single material, extend between and electrically couple various components within electronic devices.

However, as the number of components within electronic devices increases, so does the need for an increased amount of bond wires to electrically connect these components. With an increase in the number of bond wires within the device, the risk of bond wires becoming crossed, overlapped, and/or inoperable also increases. For example, bond wires extending from and electrically connecting memory dies to a substrate often become disconnected from a contact formed on the memory die/substrate, rendering the bond wire inoperable. In other examples, these bond wires can be swept and/or sag within the semiconductor package, which reduces the reliability and performance of the bond wires, and in turn, the semiconductor package as a whole. Furthermore, with an increase in the number of bond wires within the electronic device, the risk of “crosstalk” or undesirable transmissions of signals caused by overlapping electromagnetic fields are imparted on conventional bond wires, which in turn causes electromagnetic interference (EMI) within the electronic device.

Accordingly, it would be beneficial to make bond wires that maintain electrical connections within the electronic devices, control electrical impedance, and reduce crosstalk with adjacent signals and/or components, without increasing the size and/or cost of the bond wire.

### SUMMARY

The present disclosure generally relates to semiconductor packages, and more particularly, to semiconductor packages including at least one die and at least one coaxial wire assembly.

In an example, the semiconductor package includes a coaxial wire assembly that extends between, contacts and electrically couples a die and a substrate of the semiconductor package. The coaxial wire assembly includes a central bond wire that electrically connects the die and the substrate, as well as various outer layers and/or materials that surround the bond wire. For example, the coaxial wire assembly includes a dielectric material layer that surrounds the bond wire. The dielectric material layer is formed from a substantially insulative material that covers and/or insulates the bond wire to reduce the inductive effect of the bond wire extending between and electrically connecting the die and the substrate. Additionally, the inclusion of dielectric material around the bond wire of the coaxial wire assembly aids in controlling and/or maintaining a uniform or desired impedance for the semiconductor package during operation. Furthermore, and because of the controlled impedance, the semiconductor package, including the coaxial wire assemblies, have increased efficiency at high speeds.

Additionally, the coaxial wire assembly can include a ground material layer that surrounds the dielectric material layer. The ground material layer is formed from an electrically conductive material that is connected to a ground pad formed in the substrate of the semiconductor package. The inclusion of the ground material layer within the coaxial wire assemblies in the semiconductor packages substantially reduces or eliminates crosstalk with adjacent components as a result of the ground material absorbing radiation and/or signals, as well as suppressing electrical fields generated by other components included within electronic device having the semiconductor package.

Furthermore, the inclusion of the coaxial wire assemblies in the semiconductor packages substantially improves the securement of the bond wire within the semiconductor package. The multi-layers of material of the coaxial wire assembly also provide rigidity to the coaxial wire assembly, which in turn reduces the movement of the coaxial wire assembly within the semiconductor package. Furthermore, by surrounding the bond wire with the dielectric material and the ground material, adjacent coaxial wire assemblies will not damage or short connections if they touch, as the bond wires are substantially protected and/or enclosed.

Accordingly, examples of the disclosure provide a semiconductor package that includes a substrate, a contact pad formed on the substrate, and a ground pad formed on the substrate, adjacent the contact pad. The semiconductor package also includes a die positioned over the substrate, adjacent the contact pad. The die includes a top surface, and a die contact pad formed on the top surface. Additionally, the semiconductor package includes a coaxial wire assembly extending between the contact pad and the die contact pad of the die. The coaxial wire assembly includes a bond wire contacting and extending between the contact pad and the die contact pad, a dielectric material surrounding the bond wire, and a ground material surrounding the dielectric material.

Additional examples of the disclosure provide a coaxial wire assembly extending between a contact pad of a substrate and a die contact pad of a die included in a semiconductor package. The coaxial wire assembly includes a bond wire contacting and extending between the contact pad and the die contact pad, and a dielectric material layer surrounding the bond wire. The coaxial wire assembly also includes a ground material layer surrounding the dielectric material layer.

Further examples of the disclosure provide a semiconductor package that includes a substrate including a first contact means and a ground means formed adjacent the first contact means. The semiconductor package also includes a die positioned over the substrate, adjacent the first contact means. The die includes a top surface, and a second contact means formed on the top surface. Additionally, the semiconductor package includes a coaxial wire assembly extending between the first contact means and the second contact means. The coaxial wire assembly includes an electrical bonding means contacting and extending between the first contact means and the second contact means, an insulative means surrounding the electrical bonding means, and a conductive means surrounding the insulative means.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a perspective view of a semiconductor package including coaxial wire assemblies according to an example.

FIG. 2 shows a side cross-sectional view of a coaxial wire assembly of the semiconductor package of FIG. 1 taken along line 2-2 according to an example.

FIG. 3 shows a front cross-sectional view of the semiconductor package of FIG. 1 taken along line 3-3 according to an example.

FIG. 4 shows a perspective view of a semiconductor package including coaxial wire assemblies and a plurality of stacked dies according to another example.

FIG. 5 shows a front cross-sectional view of the semiconductor package of FIG. 4 taken along line 5-5 according to an example.

FIG. 6 shows a flowchart illustrating processes for creating semiconductor packages including coaxial wire assemblies according to an example.

FIG. 7A-FIG. 7G show front cross-sectional views of a semiconductor package undergoing processes for creation similar to those shown in FIG. 6 according to an example.

FIG. 8A-FIG. 8D show front cross-sectional views of a semiconductor package undergoing processes for creation similar to those shown in FIG. 6 according to another example.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to semiconductor packages, and more particularly, to semiconductor packages including coaxial wire assemblies. In an example, the coaxial wire assembly includes a central bond wire that electrically connects a die and a substrate of the semiconductor package, as well as various outer layers and/or materials that surround the bond wire. For example, the coaxial wire assembly includes a dielectric material layer that surrounds the bond wire. Additionally, the coaxial wire assembly includes a ground material layer that surrounds the dielectric material layer.

Forming coaxial wire assembly to be included in semiconductor packages imparts many technical benefits including, but not limited to, reducing the inductive effect of the bond wire extending between and electrically connecting the die and the substrate, as well as aiding in controlling and/or maintaining a uniform or desired impedance for the semiconductor package during operation. The controlled impedance in turn increases efficiency at high speeds of the semiconductor package. Additional benefits include, but are not limited to, substantially reducing or eliminating crosstalk with adjacent components as a result of materials in the coaxial wire assembly absorbing radiation and/or signals, as well as suppressing electrical fields generated by other components. Moreover, benefits include, but are not limited to, improving bond wiring securement within the package, providing structural support to the connections in the semiconductor package, and substantially preventing damage and/or shorts of the bond wire included therein.

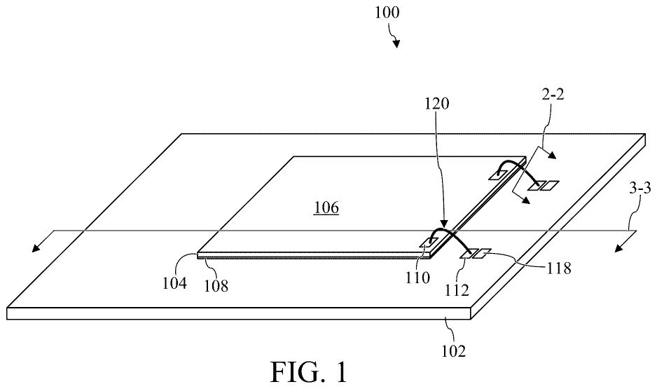

These and other examples are discussed below with reference to FIG. 1-FIG. 8D. However, those skilled in the art will readily appreciate that the detailed description given herein with respect to these Figures is for explanatory purposes only and should not be construed as limiting.

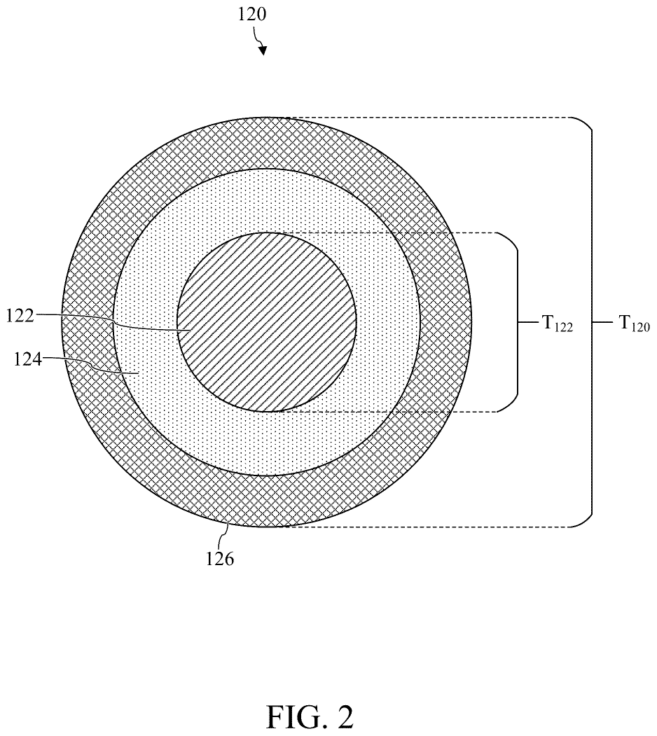

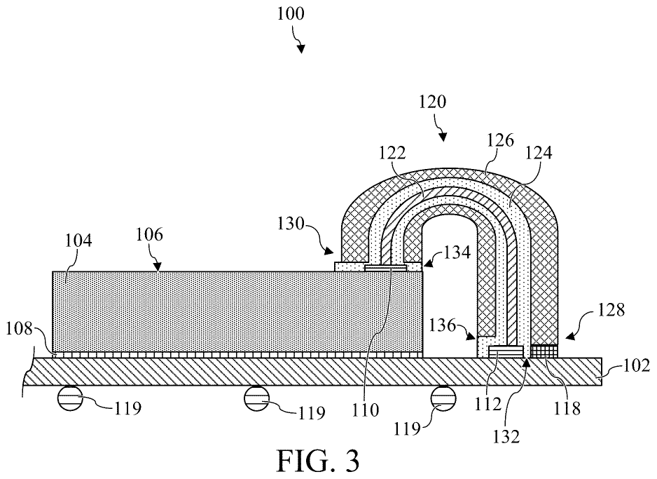

Turning to FIG. 1-FIG. 3, a semiconductor package 100 (hereafter, “semiconductor package 100”) is shown in various views. More specifically, FIG. 1 shows a perspective view of semiconductor package 100, FIG. 2 shows a cross-sectional side view of a coaxial wire assembly included in semiconductor package 100 taken along line 2-2 in FIG. 1, and FIG. 3 shows a cross-sectional front view of semiconductor package 100 including the coaxial wire assembly taken along line 3-3 in FIG. 1.

In the non-limiting example, semiconductor package 100 includes a substrate 102. Substrate 102 forms the base layer for semiconductor package 100. Substrate 102 is formed as a semiconducting material and/or is formed from as any suitable material or material composition that includes semiconducting properties/characteristics. For example, substrate 102 is formed from indium phosphide (InP) or Indium gallium arsenide (InGaAs). In other non-limiting examples, substrate 102 is formed from, without limitation, substances consisting essentially of one or more compound semiconductors. Substrate 102 can also be formed as a bulk substrate or as part of a silicon-on-insulator (SOI) wafer. Additionally, or alternatively, substrate 102 is formed from, for example, silicon (Si), silicon carbide (SiC), germanium (Ge), germanium oxide (GeO), cadmium zinc telluride (CdZnTe), or gallium arsenide (GaAs). Furthermore, substrate 102 is fabricated as a layer of semiconductor material, substances or materials consisting essentially of one or more compound semiconductors having a composition defined by the formula AlX1GaX2InX3AsY1PY2NY3SbY4, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substances can include II-VI compound semiconductors having a composition ZnA1CdA2SeB1TeB2, where A1, A2, B1, and B2 are relative proportions each greater than or equal to zero and A1+A2+B1+B2=1 (1 being a total mole quantity).

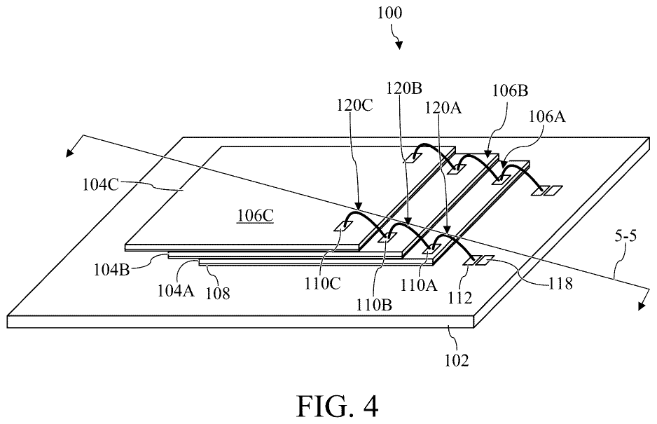

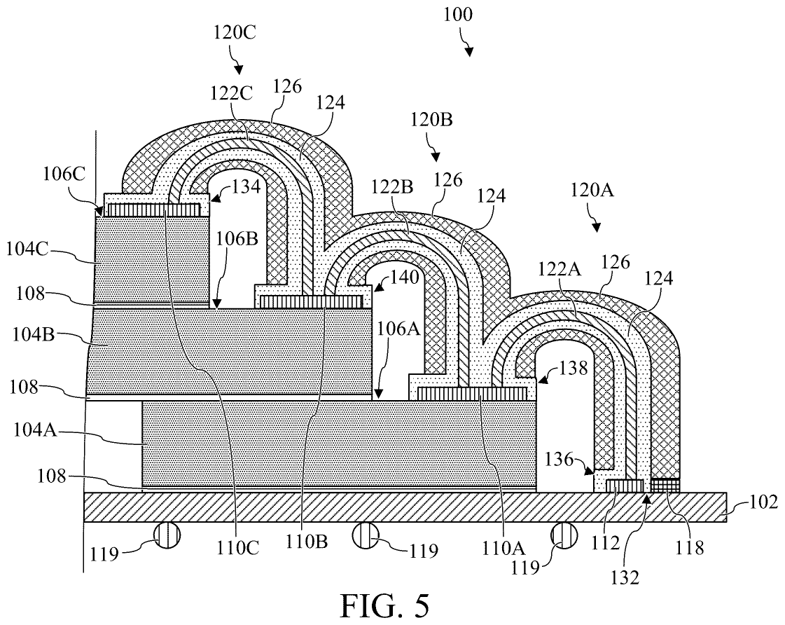

Semiconductor package 100 also includes at least one die 104 including a top surface 106. As shown in FIG. 1 and FIG. 3, die 104 is disposed over, positioned on, and/or formed above substrate 102. In a non-limiting example, die 104 of semiconductor package 100 are formed as NAND memory dies. However, it is understood that die 104 can be formed as any volatile or non-volatile memory die, or any other suitable circuit stack-up configuration. Additionally in the non-limiting example shown in FIG. 1 and FIG. 3, die 104 of semiconductor package 100 includes a single die 104 disposed over substrate 102. It is understood that the number of dies included in semiconductor package is illustrative, and semiconductor package 100 can include any suitable number of dies to form stacked dies 104 of, for example, a memory device (see, FIG. 4 and FIG. 5).

As shown in FIG. 1-FIG. 3, semiconductor package 100 also includes a die attach film (DAF) 108 (hereafter, “DAF 108”). DAF 108 is disposed between die 104 and substrate 102. More specifically, DAF 108 is disposed over and/or substantially cover a bottom surface of die 104, opposite top surface 106, to bond or connect dies 104 to substrate 102. In a non-limiting example, die 104 positioned adjacent substrate 102 is coupled and/or connected directly to substrate 102 via DAF 108. DAF 108 is formed as any suitable adhesive material capable of withstanding the operational parameters, characteristics, and/or constraints (e.g., temperature change) of semiconductor package 100.

Die 104 includes at least one die pad, die connection pad, or die contact pad 110 (hereafter, “die contact pad 110”). As shown in FIG. 1, die 104 includes a die contact pad 110 formed in die 104 and/or on the uncovered top surface 106. For example, die 104 includes a plurality of die contact pads 110 formed directly in die 104 and/or directly on top surface 106 of die 104. As shown in the non-limiting example, die contact pads 110 are formed directly in die 104 and/or directly on top surface 106 of die 104. As discussed herein, die contact pads 110 are used to electrically couple die 104 to substrate 102, via contact pad 112 of substrate 102. Die contact pads 110 formed in die 104 are of a predetermined configuration and/or circuitry based on operational and/or structural parameters of semiconductor package 100. It is understood that the number of die contact pads 110 and/or the configuration of die contact pads 110 of semiconductor package 100 shown in FIG. 1 and FIG. 3 is illustrative. As such, other non-limiting examples of semiconductor package 100 can include more or less die contact pads 110 and/or can include distinct configurations or circuitry than the non-limiting example shown in FIG. 1.

As shown in FIG. 1 and FIG. 3, at least one contact pad 112 is formed directly in and/or directly on substrate 102. That is, substrate 102 includes at least one contact pad 112 formed thereon and/or formed therein. Contact pad 112 is formed on and/or in substrate 102 adjacent die 104 and/or DAF 108 directly disposed over substrate 102. As discussed herein, a coaxial wire assembly 120 extends between and/or electrically couples contact pad 112 of substrate 102 and at least one corresponding die contact pad 110 formed in die 104. In the non-limiting example shown in FIG. 1, substrate 102 of semiconductor package 100 includes a two (2) distinct contact pads 112 formed in and/or on substrate 102. It is understood that the number of contact pads included in semiconductor package, and more specifically substrate 102, is illustrative, and semiconductor package 100 can include any suitable number of contact pads 112 of, for example, a memory device. Additionally, or alternatively, the number of contact pads 112 formed directly in and/or directly on substrate 102 is dependent on, at least in part, the number of corresponding die contact pads 110 formed in and/or on die 104.

Adjacent contact pad 112 is a ground pad 118. More specifically, substrate 102 includes at least one ground pad 118 formed directly on and/or directly in substrate 102, substantially adjacent to contact pad 112. In the non-limiting example shown in FIG. 1 and FIG. 3, ground pad 118 formed directly on and/or directly in substrate 102 is also spaced apart and/or separated from the adjacent contact pad 112 formed on/in substrate 102. As discussed herein, ground pad 118 absorbs, suppresses, and/or substantially dissipates electrical dischargers and/or electromagnetic fields generated by semiconductor package 100 during operation. As such, ground pad 118 of substrate 102 is formed form any suitable electrically conductive material including, but not limited to, copper (Cu), silver (Ag), gold (Au), aluminum (Al), palladium (Pd), platinum (Pt), nickel (Ni), silicon carbide (SiC), silver alloy, gold alloy, and the like. In the non-limiting example shown in FIG. 1, substrate 102 of semiconductor package 100 includes two (2) distinct ground pads 118 formed in and/or on substrate 102. It is understood that the number of ground pads included in semiconductor package 100, and more specifically substrate 102, is illustrative, and semiconductor package 100 can include any suitable number of ground pads 118 of, for example, a memory device. Additionally, or alternatively, the number of ground pads 118 formed directly in and/or directly on substrate 102 is dependent on, at least in part, the number of corresponding contact pads 112 formed in and/or on substrate 102.

Semiconductor package 100 includes a plurality of solder bumps 119 formed on substrate 102. More specifically, and as shown in FIG. 3, a plurality of solder bumps 119 are formed, disposed, and/or positioned on a surface of substrate 102, opposite die 104, contact pad 112, and/or ground pad 118. Solder bumps 119 facilitate the electrical coupling of semiconductor package 100, and the various components included therein (e.g., die 104), to distinct electronic components in a device (not shown) including semiconductor package 100. In non-limiting examples, solder bumps 119 can be formed as any suitable structure and/or from any suitable material configured to electrical couple semiconductor package 100 to distinct portions of a device, including, but not limited to, copper (Cu) bumps or pillars, solder balls and/or the like.

Semiconductor package 100 also includes coaxial wire assemblies 120 for electrically connecting various components therein. More specifically, semiconductor package 100 includes a coaxial wire assembly 120 extending between, contacting, electrically connecting, and/or communicatively coupling die 104 to substrate 102. As shown in the non-limiting example of FIG. 1 and FIG. 3, at least a portion of each coaxial wire assembly 120 extends between and/or directly contacts contact pad 112 of substrate 102 and die contact pad 110 of die 104. In the non-limiting example, coaxial wire assembly 120 electrically connects, communicatively couples, and/or forms a transmission path between die 104 and substrate 102. Semiconductor package 100 includes two (2) distinct coaxial wire assemblies 120. It is understood that the number of coaxial wire assemblies 120 included in semiconductor package 100 is illustrative, and semiconductor package 100 can include any suitable number of coaxial wire assemblies of, for example, a memory device. Additionally, or alternatively, the number of coaxial wire assemblies 120 included in semiconductor package 100 is dependent on, at least in part, the number of contact pads 112 of substrate 102 and/or number of die contact pads 110 of die 104.

Turning to FIG. 2 and FIG. 3, coaxial wire assemblies 120 that are configured to electrically couple substrate 102 and die 104 are formed from a plurality of distinct materials and/or layers. In non-limiting examples, an electrically conductive core layer is formed as and/or includes a bond wire 122. Core bond wire 122 is formed from any suitable material that includes conductive and/or electrical properties to form an electrical transmission path between different components of semiconductor package 100. For example, bond wire 122 of coaxial wire assembly 120 is formed from gold (Au) wire. As shown in FIG. 3, bond wire 122 of coaxial wire assembly 120 extends between and directly contacts contact pad 112 of substrate 102 and die contact pad 110 of die 104 to electrically couple and/or form an electrical transmission path between substrate 102 and die 104, respectively. As discussed herein, and as a result of forming coaxial wire assembly 120 from a plurality of layers, bond wire 122 can include a smaller thickness, while maintaining electrical coupling, controlling impedance, and/or reducing crosstalk with adjacent signals and/or components. In a non-limiting example, bond wire 122 of coaxial wire assembly 120 can include a thickness (T₁₂₂) between approximately 5 microns (μm) and approximately 20 μm.

As shown in FIG. 2 and FIG. 3, coaxial wire assembly 120 also include a dielectric material 124 surrounding bond wire 122. More specifically, dielectric material 124 is a layer of material for coaxial wire assembly 120 that is formed around and/or substantially surrounds bond wire 122 within semiconductor package 100. Dielectric material 124 is formed from any suitable material that includes insulating and/or electrically insulative properties to insulate and/or protect bond wire 122 of coaxial wire assembly 120 during operation. For example, dielectric material 124 is formed from materials including, but not limited to, silicon dioxide, silicon nitride, aluminum oxide, high-k dielectrics, low-k dielectrics, organic dielectrics, glass, acrylic, polyurethane, epoxy, polymers, and the like. In a non-limiting example, dielectric material 124 of coaxial wire assembly 120 can include a thickness between approximately 2 μm and approximately 30 μm.

Additionally in non-limiting examples, coaxial wire assembly 120 includes a ground material 126 surrounding dielectric material 124. That is, ground material 126 includes an outer, conductive material layer of coaxial wire assembly 120 that is formed around and/or substantially surrounds dielectric material 124. Additionally, and as shown in FIG. 2, ground material 126 substantially surrounds and/or is circumferentially disposed around bond wire 122. Ground material 126 is formed from any suitable material that includes electrical and/or conductive properties to reduce crosstalk between adjacent components (e.g., distinct coaxial wire assemblies 120) and/or suppress electromagnetic fields during operation of semiconductor package 100, as discussed herein. For example, ground material 126 is formed from materials including, but not limited to, metals, metal alloys, and the like. Additionally, ground material 126 of coaxial wire assembly 120 can include a thickness between approximately 2 μm and approximately 30 μm. As a result, the overall thickness (T₁₂₀) of coaxial wire assembly 120 can be approximately 9 μm microns and approximately 80 μm microns.

Turning to FIG. 3, a cross-sectional view of substrate 102, die 104, and coaxial wire assembly 120 for semiconductor package 100 is shown. In the non-limiting example, bond wire 122 of coaxial wire assembly 120 extends between and directly contacts contact pad 112 formed in substrate 102 and die contact pad 110 formed in die 104. That is, a first end 128 of coaxial wire assembly 120 includes a portion of bond wire 122 that contacts, connects, and/or is electrically coupled to contact pad 112 of substrate 102, while a second end 130, opposite first end 128, of coaxial wire assembly 120 includes a portion of bond wire 122 that contacts, connects, and/or is electrically coupled to die contact pad 110 of die 104.

Additionally as shown in the non-limiting example of FIG. 3, a portion or region 132 of dielectric material 124 of coaxial wire assembly 120 is disposed between contact pad 112 and ground pad 118. More specifically, region 132 of dielectric material 124 formed within and/or adjacent first end 128 of coaxial wire assembly 120 is disposed, formed, and/or positioned between contact pad 112 and ground pad 118, respectively, of substrate 102. As a result, and in the non-limiting example, region 132 of dielectric material 124 positioned between contact pad 112 and ground pad 118 substantially separates contact pad 112 and ground pad 118, and/or prevents at least a portion of ground material 126 of coaxial wire assembly 120 from contacting and/or being disposed over contact pad 112 of substrate 102.

In non-limiting examples where semiconductor package 100 includes a single die 104, dielectric material 124 of coaxial wire assembly 120 also includes a first extended portion 134 disposed directly over at least a portion of top surface 106 of die 104. More specifically, and as shown in FIG. 3, second end 130 of coaxial wire assembly 120 includes first extended portion 134 of dielectric material 124 formed, disposed, and/or positioned over at least a portion of die contact pad 110, as well as a portion of exposed, top surface 106 of die 104, adjacent die contact pad 110. In the non-limiting example, first extending portion 134 of dielectric material 124 for coaxial wire assembly 120 substantially covers, extends beyond, and/or envelops die contact pad 110 of die 104. Additionally as shown, extended portion 134 of dielectric material 124 for coaxial wire assembly 120 also substantially surrounds bond wire 122 included in second end 130 of coaxial wire assembly 120. Forming first extend portion 134 in dielectric material 124 of coaxial wire assembly 120 substantially prevents ground material 126 from contacting top surface 106 and/or die contact pad 110 of die 104. As shown in the non-limiting examples, extended portion 134 of dielectric material 124 for coaxial wire assembly 120 is disposed and/or positioned between top surface 106 of die 104 and an end of ground material 126 (e.g., second end 130 of coaxial wire assembly 120).

Additionally, dielectric material 124 of coaxial wire assembly 120 also includes a second extended portion 136 disposed directly over at least a portion of contact pad 112. As shown in FIG. 3, first end 128 of coaxial wire assembly 120 includes second extended portion 136 of dielectric material 124 formed, disposed, and/or positioned over at least a portion of contact pad 112 of substrate 102. Additionally as shown, second extended portion 136 of dielectric material 124 for coaxial wire assembly 120 is also positioned adjacent die 104 and/or opposite ground pad 118. Furthermore, second extended portion 136 is also disposed over a portion of substrate 102 directly adjacent contact pad 112 and/or between contact pad 112 and die 104. In the non-limiting example, second extended portion 134 of dielectric material 124, along with region 132, substantially cover, extend beyond, and/or envelop contact pad 112 for substrate 102. Including second extended portion 136 in dielectric material 124 of coaxial wire assembly 120 substantially prevents ground material 126 from contacting contact pad 112 of substrate 102. In the non-limiting examples, second extended portion 136 of dielectric material 124 for coaxial wire assembly 120 is disposed and/or positioned between an end of ground material 126 (e.g., first end 128 of coaxial wire assembly 120) and contact pad 112.

Ground material 126 of coaxial wire assembly 120 contacts ground pad 118 of substrate 102. More specifically, and as shown in FIG. 3, an end of ground material 126 adjacent first end 128 of coaxial wire assembly 120 directly contacts, is disposed over, and/or substantially covers ground pad 118 form in and/or on substrate 102. As discussed herein, ground material 126 is formed from any suitable material that includes electrical and/or conductive properties to reduce crosstalk between adjacent components (e.g., distinct coaxial wire assemblies 120) and/or suppress electromagnetic fields during operation of semiconductor package 100. During operation, ground material 126 of coaxial wire assembly 120 substantially absorbs, attracts, and/or dissipates crosstalk/electromagnetic fields by passing such signals or waves through ground pad 118 of substrate 102.

FIG. 4 and FIG. 5 show various views of additional examples of semiconductor package 100. More specifically, FIG. 4 shows a perspective view of semiconductor package 100, and FIG. 5 shows a cross-sectional front view of semiconductor package 100 including a plurality of coaxial wire assemblies 120 taken along line 5-5 in FIG. 4. It is understood that similarly numbered and/or named components may function in a substantially similar fashion. Redundant explanation of these components has been omitted for clarity and/or brevity.

In the non-limiting example shown in FIG. 4 and FIG. 5, semiconductor package 100 also includes a plurality of stacked dies 104A, 104B, 104C. As shown in FIG. 4 and FIG. 5, the plurality of stacked dies 104A, 104B, 104C are disposed over, positioned on, and/or formed above substrate 102. In the non-limiting example, the plurality of stacked dies 104A, 104B, 104C are staggered or stepped with respect to one another when disposed over substrate 102. As such, at least a portion of a top surface 106 for each die of the plurality of stacked dies 104A, 104B, 104C is uncovered by the adjacent die positioned thereon. Additional materials and/or structures cover the uncovered top surfaces 106 of the plurality of stacked dies 104A, 104B, 104C in semiconductor package 100 (e.g., molding compound). Additionally, and as shown, the plurality of stacked dies 104A, 104B, 104C includes a top die 104C positioned opposite and/or above the substrate, and is formed over all remaining die of the plurality of stacked dies 104A, 104B.

In a non-limiting example, the plurality of stacked dies 104A, 104B, 104C of semiconductor package 100 are formed as NAND memory dies. However, it is understood that the plurality of stacked dies 104A, 104B, 104C can be formed as any volatile or non-volatile memory die, or any other suitable circuit stack-up configuration. Additionally in the non-limiting example shown in FIG. 4 and FIG. 5, the plurality of stacked dies 104A, 104B, 104C include three (3) dies. It is understood that the number of dies included in the plurality of stacked dies 104A, 104B, 104C is illustrative, and semiconductor package 100 can include any suitable number of dies to form the stacked dies 104A, 104B, 104C. Furthermore, although only a single plurality of stacked dies 104A, 104B, 104C are shown in FIG. 4 and FIG. 5, it is understood that semiconductor package 100 can include more than one plurality of stacked dies, where each of the plurality of stacked dies is disposed or formed over substrate 102, adjacent to one another.

As shown in FIG. 4 and FIG. 5, semiconductor package 100 also includes a plurality of die attach films (DAF) 108. Each of the plurality of DAF 108 is disposed between each of the plurality of stacked dies 104A, 104B, 104C and/or between die 104A and substrate 102. More specifically, DAF 108 are disposed over and/or substantially cover a bottom surface of each of the plurality of stacked dies 104A, 104B, 104C, opposite top surface 106A, 106B, 106C, to bond or connect dies 104A, 104B, 104C to adjacent dies and/or substrate 102. DAF 108 is formed as any suitable adhesive material capable of withstanding the operational parameters, characteristics, and/or constraints (e.g., temperature change) of semiconductor package 100.

Each of the plurality of stacked dies 104A, 104B, 104C includes at least one die pad, connection pad, or die contact pad 110A, 110B, 110C (hereafter, “die contact pad 110A, 110B, 110C”). As shown in FIG. 4, each die 104A, 104B, 104C includes a die contact pad 110A, 110B, 110C formed in die 104A, 104B, 104C and/or on the uncovered (portion) of top surface 106A, 106B, 106C. For example, top die 104C includes a plurality of die contacts 110C formed directly in top die 104C and/or directly on top surface 106C of top die 104C. Each distinct die of the plurality of dies 104A, 104B formed below and/or between top die 104C and substrate 102 also includes a plurality of die contact pads 110A, 110B. As shown in the non-limiting example, die contact pads 110A, 110B are formed directly in respective dies 104A, 104B and/or directly on the uncovered top surfaces 106A, 106B for each die of the plurality of dies 104A, 104B. As discussed herein, the plurality of die contact pads 110A, 110B, 110C are used to electrically couple each of the distinct dies 104A, 104B, 104C to one another, and/or to electrically couple the die(s) 104A, 104B, 104C to substrate 102, via substrate contact pad 112. Die contacts 110A, 110B, 110C formed in the plurality of dies 104A, 104B, 104C are of a predetermined configuration and/or circuitry based on operational and/or structural parameters of semiconductor package 100. It is understood that the number of die contact pads 110A, 110B, 110C and/or the configuration of die contact pads 110A, 110B, 110C of semiconductor package 100 shown in FIG. 4 and FIG. 5 is illustrative. As such, other non-limiting examples of semiconductor package 100 can include more or fewer die contact pads 110A, 110B, 110C and/or can include distinct configurations or circuitry than the non-limiting example shown in FIG. 4 and FIG. 5.

Semiconductor package 100 also includes a plurality of coaxial wire assemblies 120A, 120B, 120C for electrically connecting various components therein. More specifically, semiconductor package 100 includes coaxial wire assemblies 120A, 120B, 120C extending between, contacting, electrically connecting, and/or communicatively coupling the plurality of dies 104A, 104B, 104C to one another, and/or to substrate 102. As shown in the non-limiting example of FIG. 4 and FIG. 5, each coaxial wire assembly 120B, 120C extends between and/or directly contact die contact pad 110A, 110B, 110C for two adjacent stacked dies 104A, 104B, 104C. For example, coaxial wire assembly 120C extends between, contacts, and/or electrically connects die contact pad 110C of top die 104C to the die contact pad 110B of the adjacent die 104B. Additionally, coaxial wire assembly 120A extends between and/or directly contacts contact pad 112 of substrate 102 and die contact pad 110A for the immediately adjacent die 104A. Furthermore, coaxial wire assembly 120B extends between, contacts, and/or electrically connects die contact pad 110A of die 104A to the die contact pad 110B of the adjacent die 104B. In the non-limiting example, each of the plurality of coaxial wire assemblies 120A, 120B, 120C electrically connect, communicatively couple, and/or form a transmission path between each of the plurality of stacked dies 104A, 104B, 104C and substrate 102, respectively.

In the non-limiting example, semiconductor package 100 shown in FIG. 4 and FIG. 5 includes six (6) coaxial wire assemblies 120A, 120B, 120C. It is understood that the number of coaxial wire assemblies 120 included in semiconductor package 100 is dependent, at least in part on, the number of dies in the plurality of stacked dies 104A, 104B, 104C, the number of distinct plurality of stacked dies 104A, 104B, 104C, the number of die contact pads 110A, 110B, 110C, the number of contact pads 112 for substrate 102, and/or the configuration/circuitry of the plurality of stacked dies 104A, 104B, 104C for semiconductor package 100.

Turning to FIG. 5, a cross-sectional front view of semiconductor package 100 includes a plurality of coaxial wire assemblies 120A, 120B, 120C. In the non-limiting example, the plurality of coaxial wire assemblies 120A, 120B, 120C each include a distinct bond wire 122A, 122B, 122C contacting and/or extending between die contact pads 110A, 110B, 110C and/or contact pad 112 substrate 102. For example, and as shown in FIG. 5, bond wire 122A of coaxial wire assembly 120A contacts, extends between, and/or electrically couples contact pad 112 of substrate 102 and die contact pad 110A of die 104A. Bond wire 122B of coaxial wire assembly 120B contacts, extends between, and/or electrically couples die contact pad 110A of die 104A and die contact pad 110B of die 104B, while bond wire 122C of coaxial wire assembly 120C contacts, extends between, and/or electrically couples die contact pad 110B of die 104B and die contact pad 110C of die 104C.

Additionally as shown in FIG. 5, dielectric material 124 and ground material 126 is formed over each of the plurality of distinct bond wires 122A, 122B, 122C. That is, and as shown in the non-limiting example, a single, continuous layer of dielectric material 124 is disposed over, formed around, and/or substantially surrounds each of the plurality of distinct bond wires 122A, 122B, 122C for coaxial wire assemblies 120A, 120B, 120C. For example, a portion of continuous dielectric material 124 substantially surrounds and/or is formed around distinct ends of both bond wire 120A and bond wire 120B, where each bond wire 120A, 120B is connected to and/or contacts die contact pad 110A of die 104A. Furthermore, a single, continuous layer of ground material 126 is disposed around, formed over, and/or substantially surrounds dielectric material 124. Ground material 126 is also disposed around each of the plurality of distinct bond wires 122A, 122B, 122C, and separated from bond wires 122A, 122B, 122C by dielectric material 124.

Region 132 of dielectric material 124 formed within and/or adjacent coaxial wire assembly 120A is disposed, formed, and/or positioned between contact pad 112 and ground pad 118, respectively, of substrate 102. As a result, and in the non-limiting example, region 132 of dielectric material 124 positioned between contact pad 112 and ground pad 118 substantially separates contact pad 112 and ground pad 118, and/or prevents at least a portion of ground material 126 from contacting and/or being disposed over contact pad 112 of substrate 102.

In non-limiting examples where semiconductor package 100 includes the plurality of dies 104A, 104B, 104C, coaxial wire assembly 120C includes first extended portion 134 of dielectric material 124 formed, disposed, and/or positioned over at least a portion of die contact pad 110C of die 104C, and top surface 106C of die 104C, respectively. Additionally as shown, extended portion 134 of dielectric material 124 for coaxial wire assembly 120C also substantially surrounds bond wire 122C. As similarly discussed herein, forming first extend portion 134 in dielectric material 124 of coaxial wire assembly 120C substantially prevents ground material 126 from contacting contact pad 110C of die 104C. As shown in the non-limiting example, extended portion 134 of dielectric material 124 for coaxial wire assembly 120C is disposed and/or positioned between die contact pad 110C of die 104C and an end of ground material 126 (e.g., end of coaxial wire assembly 120C).

Additionally, dielectric material 124 of coaxial wire assembly 120A also includes second extended portion 136 disposed directly over at least a portion of contact pad 112. As shown in FIG. 5, coaxial wire assembly 120A includes second extended portion 136 of dielectric material 124 formed, disposed, and/or positioned over at least a portion of contact pad 112, as well as a portion of substrate 102, between contact pad 112 and die 104A. Additionally as shown, second extended portion 136 of dielectric material 124 is also positioned adjacent die 104A and/or opposite ground pad 118. Including second extended portion 136 in dielectric material 124 of coaxial wire assembly 120A substantially prevents ground material 126 from contacting contact pad 112 of substrate 102. In the non-limiting examples, second extended portion 136 of dielectric material 124 is disposed and/or positioned between an end of ground material 126 (e.g., end of coaxial wire assembly 120A) and contact pad 112.

Ground material 126 of coaxial wire assembly 120A also contacts ground pad 118 of substrate 102. More specifically, and as shown in FIG. 5, an end of ground material 126 included in coaxial wire assembly 120A directly contacts, is disposed over, and/or substantially covers ground pad 118 form in and/or on substrate 102. During operation, ground material 126 of the plurality of coaxial wire assemblies 120A, 120B, 120C substantially absorbs, attracts, and/or dissipates crosstalk/electromagnetic fields by passing such signals or waves through ground pad 118 of substrate 102.

When forming semiconductor package 100 including a plurality of dies 104A, 104B, 104C, segments of ground material 126 included in coaxial wire assemblies 120A, 120B, 120C are “floating” and/or do not directly contact die 104 of semiconductor package 100. As shown in the non-limiting example of FIG. 5, portions or segments of ground material 126 positioned adjacent distinct dies 104A, 104B do not contact die 104A, 104B or die contact pads 110A, 110B. More specifically, a segment of ground material 126 included in coaxial wire assembly 120B that is positioned adjacent die 104B does not contact die 104A or die contact pad 110A, but rather contacts and/or is disposed over a portion of dielectric material 124. Similarly, a segment of ground material 126 included in coaxial wire assembly 120C positioned adjacent die 104C does not contact die 104B or die contact pad 110B. Instead, ground material 126 of coaxial wire assembly 120C contacts and/or is disposed over a portion of dielectric material 124, as discussed herein.

Additionally in the non-limiting example shown in FIG. 5, dielectric material 124 can include third extended portion 138 and fourth extended portion 140, respectively, to prevent ground material 126 from undesirably contacting die contact pads 110A, 110B. For example, third extended portion 138 of dielectric material included in coaxial wire assemble 120A is formed, disposed, and/or positioned over at least a portion of die contact pad 110A of die 104A - opposite distinct die 104B. Specifically in the non-limiting example of FIG. 5, third extended portion 138 substantially covers, extends beyond, and/or envelops die contact pad 110A of die 104A. Additionally as shown, third extended portion 138 of dielectric material 124 for coaxial wire assembly 120A also is formed substantially adjacent bond wire 122A and/or covers at least a portion of surface 106A of die 104A, adjacent die contact pad 110A. Third extend portion 138 in dielectric material 124 of coaxial wire assembly 120A substantially prevents ground material 126 of coaxial wire assembly 120A from contacting contact pad 110A of die 104A. As shown in the non-limiting example, third extended portion 138 of dielectric material 124 is disposed and/or positioned between die contact pad 110A of die 104A and an end of ground material 126 (e.g., end of coaxial wire assembly 120A), such that ground material 126 contacts third extend portion 138 of dielectric material 124.

Fourth extended portion 140 of dielectric material included in coaxial wire assemble 120B is formed, disposed, and/or positioned over at least a portion of die contact pad 110B of die 104B - opposite distinct die 104C. In the non-limiting example of FIG. 5, fourth extended portion 140 substantially covers, extends beyond, and/or envelops die contact pad 110B of die 104B. Fourth extended portion 140 of dielectric material 124 for coaxial wire assembly 120B also is formed substantially adjacent bond wire 122B and/or covers at least a portion of surface 106B of die 104B, adjacent die contact pad 110B. Fourth extend portion 140 in dielectric material 124 of coaxial wire assembly 120B substantially prevents ground material 126 of coaxial wire assembly 120B from contacting contact pad 110B of die 104B. In the non-limiting example, fourth extended portion 140 of dielectric material 124 is disposed and/or positioned between die contact pad 110B of die 104B and an end of ground material 126 (e.g., end of coaxial wire assembly 120B), such that ground material 126 contacts fourth extend portion 140 of dielectric material 124.

Although shown and discussed herein as including a single, continuous dielectric material 124 and single, continuous ground material 126 included in and/or spanning across the plurality of coaxial wire assemblies 120A, 120B, 120C, it is understood that each coaxial wire assembly 120A, 120B, 120C can include distinct bond wires 122, dielectric material 124, and/or ground material 126. That is, and as discussed herein, dielectric material 124 and/or ground material 126 may not be a continuous, single layer of material. Rather, each distinct coaxial wire assembly 120A, 120B, 120C of semiconductor package 100 can include distinct dielectric material 124 formed around the corresponding bond wire 122A, 122B, 122C of each coaxial wire assembly 120A, 120B, 120C. Additionally, or alternatively, distinct ground material 126 can be formed around and/or substantially surround dielectric material for each coaxial wire assembly 120A, 120B, 120C.

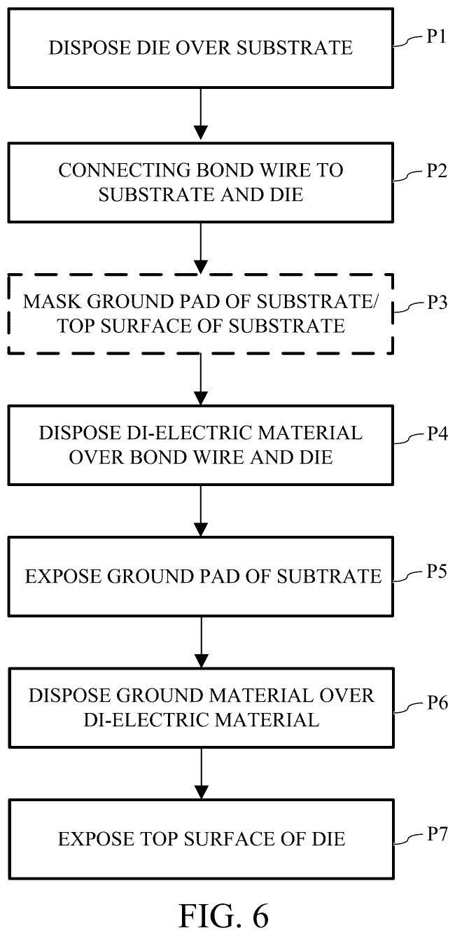

FIG. 6 shows example processes for creating a semiconductor package. Specifically, FIG. 6 is a flowchart depicting one example process for creating a semiconductor package including a single die and at least one coaxial wire assembly electrically coupling the die to a substrate. In some cases, the processes can form the various non-limiting examples of semiconductor package 100, as discussed above with respect to FIG. 1-FIG. 3.

In process P1, a die is disposed over a substrate. More specifically, a die is disposed over, positioned on, and/or attached to the substrate, as is known in the art. As such, a top surface of the die is exposed. The die includes at least one die contact pad formed directly in and/or directly on the exposed top surface. The substrate also includes at least one contact pad formed therein and/or thereon, as well as at least one ground pad formed in and/or on the substrate, adjacent the contact pad. Die contact(s) pad and contact(s) pad of the substrate are formed in a predetermined configuration, dependent on die device type and size (e.g., NAND memory device).

In process P2, a bond wire is connected to the die and the substrate. More specifically, a bond wire is connected, contacted, extended between, and/or electrically coupled to the die contact pad formed in/on the top surface of the die, and the contact pad formed in/on the substrate. The connecting and/or electrical coupling of the die contact pad and the contact pad of the substrate creates and/or forms a transmission path between the die and the substrate. This connection can be made using a commercially available wire bonding machine.

In process P3 (shown in phantom as optional), the ground pad of the substrate is masked. More specifically, the ground pad formed in or on the substrate, adjacent the contact pad, is masked, covered, and/or protected by a masking material disposed over the exposed surface of the ground pad. In non-limiting examples, masking material is disposed over the exposed surface of the ground pad using any suitable material deposition technique and/or process including, but not limited to, spray coating of photoresist material or similar processes. As discussed herein, the masking material can prevent distinct material from being formed over and/or deposited on the ground pad during subsequent processes.

Additionally, or alternatively in process P3 (shown in phantom as optional), at least a portion of the die is masked. More specifically, at least a portion of the top surface of the die, adjacent the die contact pad, is masked, covered, and/or protected by a masking material disposed over the exposed, top surface of the die. In non-limiting examples, masking material is disposed over the top surface of the die using any suitable material deposition technique and/or process to prevent distinct material from being formed over and/or deposited on the die during subsequent processes.

In process P4, a dielectric material is disposed over the bond wire. More specifically, a dielectric material is disposed over, covers, and/or substantially surrounds the bond wire extending between the contact pad of the substrate and the die contact pad of the die. Additionally, the dielectric material is also disposed over at least a portion of the top surface of the die, and at least a portion of the contact pad of the substrate. Disposing the dielectric material over the bond wire also includes disposing the dielectric material between the contact pad and the ground pad of the substrate. That is, in disposing the dielectric material over the bond wire, a region of the dielectric material is disposed, formed, and/or positioned between the contact pad and the ground pad, respectively, of the substrate. In non-limiting examples where the ground pad is masked (e.g., process P3), the region of the dielectric material disposed between the contact pad and the ground pad is also disposed adjacent to the masking material. In another non-limiting example where ground pad is not masked (e.g., “NO” to process P3), dielectric material is also disposed over the surface of the ground pad of the substrate as well.

Additionally, the disposing of the dielectric material over the bond wire in process P4 also includes forming a first extended portion and a second extend portion of the dielectric material. Specifically, disposing the dielectric material over the bond wire includes forming the first extended portion of the dielectric material directly over at least a portion of the top surface of the die and/or at least a portion of the die contact pad of the die. The formed first extended portion of the dielectric material substantially surrounds the bond wire connected to the die contact pad of the die. Forming the first extended portion of the dielectric material can also include removing a segment of the dielectric material disposed over the top surface of the die in response to the dielectric material being disposed over the entirety of the top surface of the die and/or in response to masking material not being disposed over any portion of the top surface of the die in process P3. Removing a segment of the dielectric material to form the first extended portion in process P4 can be performed using any suitable material removal technique and/or process including, but not limited to, dry or plasma etching, patterning, photolithography, or the like.

Additionally, disposing the dielectric material over the bond wire includes forming the second extended portion of the dielectric material directly over at least a portion of the contact pad of the substrate. In the non-limiting example, the second extended portion of the dielectric material is formed, disposed, and/or positioned over at least a portion of the contact pad of the substrate, adjacent the die and/or opposite the ground pad of the substrate.

The dielectric material is disposed over the bond wire, and various portions of the semiconductor package as discussed herein, using any suitable material deposition technique and/or process including, but not limited to, chemical vapor deposition (CVD), spray dielectric coating, and the like. Additionally, the dielectric material disposed in process P4 is formed from any suitable material that includes insulating and/or electrically insulative properties to insulate and/or protect the bond wire during operation. For example, dielectric material is formed from materials including, but not limited to, silicon dioxide, silicon nitride, aluminum oxide, high-k dielectrics, low-k dielectrics, organic dielectrics, glass, acrylic, polyurethane, epoxy, polymers, and the like.

In process P5, the ground pad of the substrate is exposed. That is, and subsequent to the disposing of the dielectric material over and/or substantially around the bond wire (e.g., process P4), the upper or top surface of the ground pad of the substrate is exposed. In non-limiting examples where masking material is used to mask the ground pad (e.g., process P3), the masking material is subsequently removed from the ground in process P5 to expose the upper surface of the ground pad. In other non-limiting examples where the ground pad is not masked, dielectric material disposed of the ground pad in process P4 is removed to expose the upper surface of the ground pad for the substrate. The masking material and/or dielectric material can be removed to expose the ground pad in process P5 using any suitable material removal technique and/or process including, but not limited to, etching, patterning, and the like.

In process P6, a ground material is disposed over the dielectric material surrounding the bond wire. More specifically, ground material is disposed over, covers, and/or substantially surrounds the dielectric material surrounding the bond wire. Disposing the ground material over the dielectric material also includes forming the ground material over the ground pad of the substrate. That is, the disposing of the ground material forms a portion or end of the ground material over the ground pad such that the ground material directly contacts, is disposed over, and/or substantially covers the ground pad form in and/or on the substrate. The disposing of the ground material over the dielectric material in turn forms and/or creates a coaxial wire assembly within the semiconductor package.

Additionally, the disposing of the ground material over the dielectric material also includes forming an end of the ground material over the first extended portion of the dielectric material. More specifically, end of the ground material adjacent the die is formed, disposed, and/or positioned over the first extended portion of the dielectric material formed over the top surface and/or the die contact pad of the die. In non-limiting examples, the extended portion of the dielectric material is positioned between the top surface and/or the die contact pad of the die and the end of the ground material formed thereover.

The disposing of the ground material over the dielectric material also includes forming a distinct end of the ground material over the second extended portion of the dielectric material. That is, an end of the ground material adjacent the contact pad and/or substrate is formed, disposed, and/or positioned over the second extended portion of the dielectric material formed over the contact pad of the substrate, adjacent the die. In non-limiting examples, the second extended portion of the dielectric material is positioned between the contact pad of the substrate and the end of the ground material formed thereover.

The ground material is disposed over the dielectric material, using any suitable material deposition technique and/or process including, but not limited to, sputter metal processes, evaporation processes, and the like. Additionally, the ground material disposed in process P6 is formed from any suitable material that includes electrical and/or conductive properties to reduce crosstalk between adjacent components and/or suppress electromagnetic fields during operation of the semiconductor package, as discussed herein. For example, the ground material is formed from materials including, but not limited to, metals, metal alloys, and the like.

In process P7, the top surface of the die is exposed. More specifically, and in response masking material masks a portion of the top surface of the die (e.g., process P3) and/or in response to the dielectric material being disposed over at least a portion of the top surface of the die (e.g., process P4), masking material and/or dielectric material is removed to expose the top surface of the die. The masking material and/or dielectric material can be removed to expose the top surface of the die in process P7 using any suitable material removal technique and/or process including, but not limited to, etching, patterning, and the like.

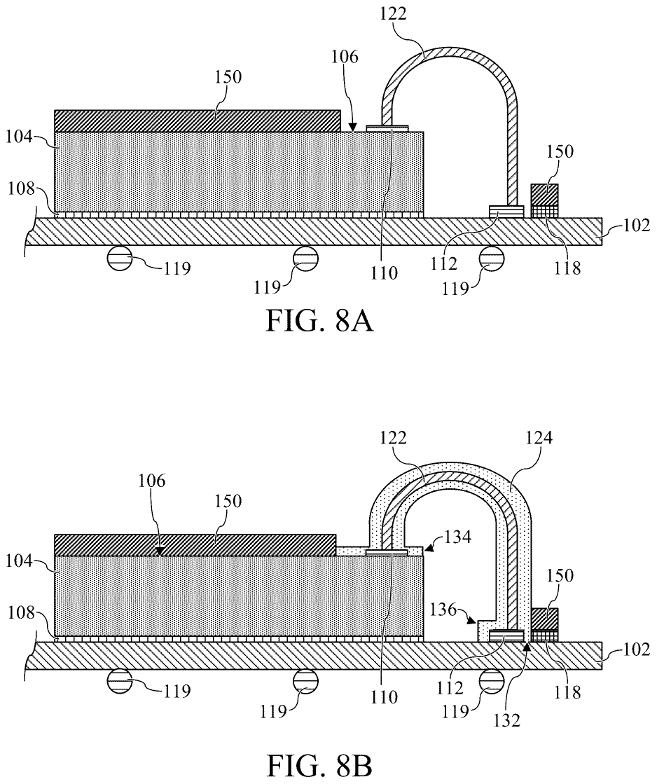

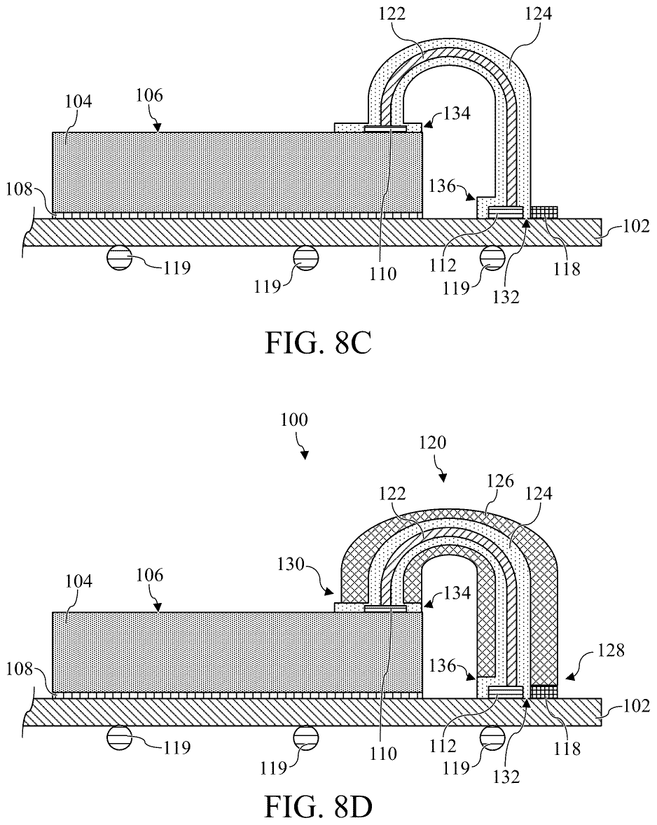

Although shown and discussed herein as being performed in order (e.g., process P1-P7), it is understood that at least some of the processes can be performed in an order distinct from that discussed herein. For example, the exposing of the top surface of the die (e.g., process P7) can be performed subsequent to the disposing of the dielectric material (e.g., process P4), prior to the disposing of the ground material (e.g., process P6), and/or prior to or simultaneous to the exposing of the ground pad (e.g., process P5). Additionally, in other non-limiting examples, the exposing of the top surface of the die can form the first extended portion of the dielectric material. That is, and as discussed herein (see, FIG. 8A-FIG. 8D), exposing the top surface of the die by removing a segment of the dielectric material disposed over the top surface can in turn form and/or define the first extended portion of the dielectric material. Furthermore, although discussed herein as forming a semiconductor package including a single die, it is understood that at least some of the processes (e.g., process P2) can be performed multiple times in order to create a semiconductor package that includes a plurality of dies and a plurality of coaxial wire assemblies extending between and electrically coupling the substrate and/or the plurality of dies.

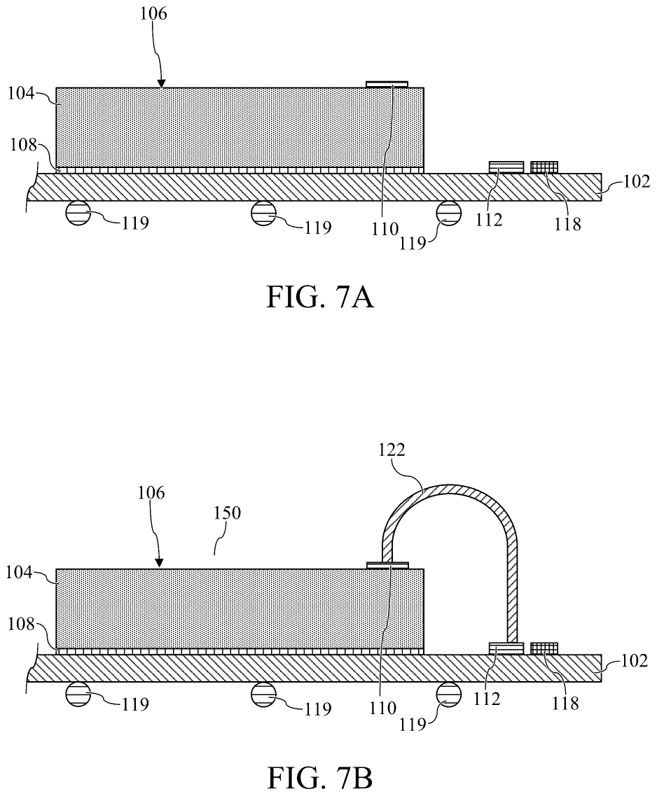

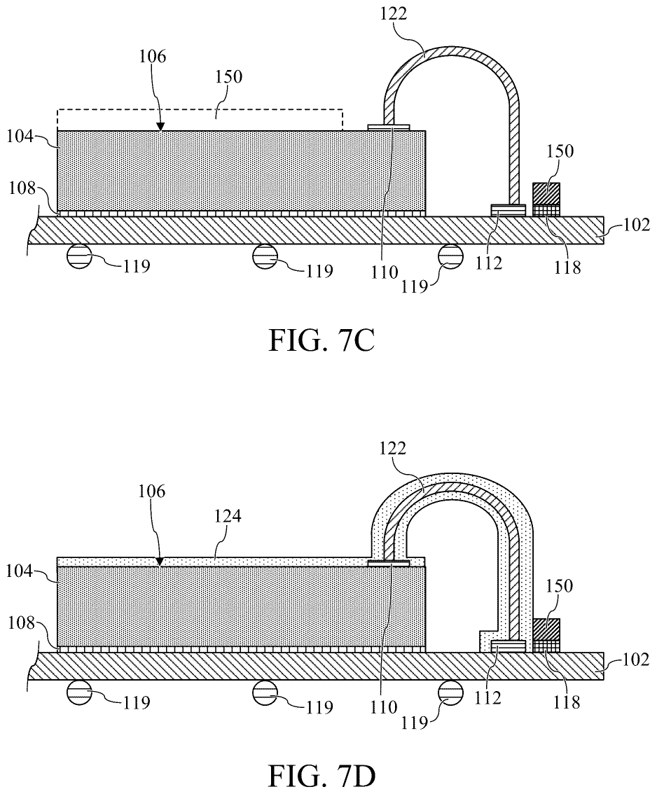

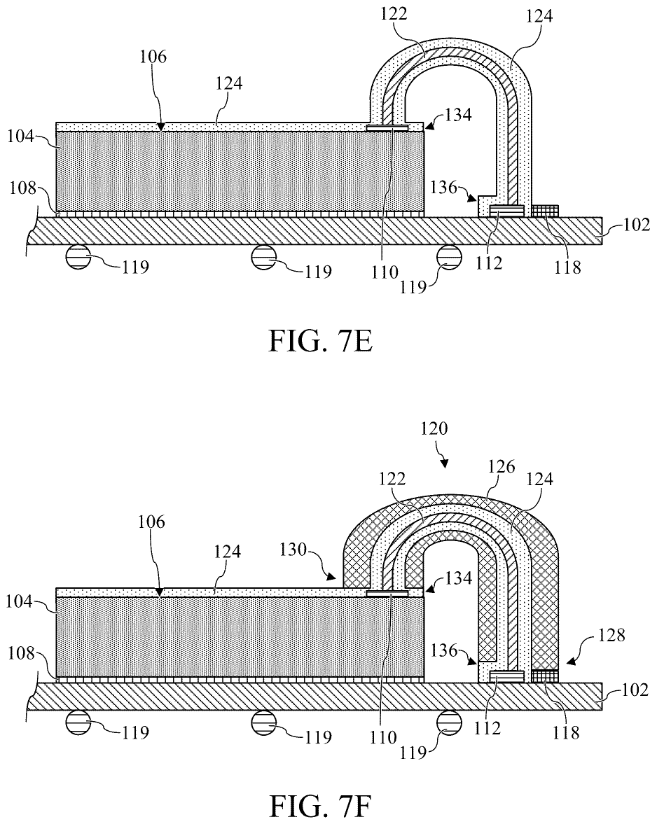

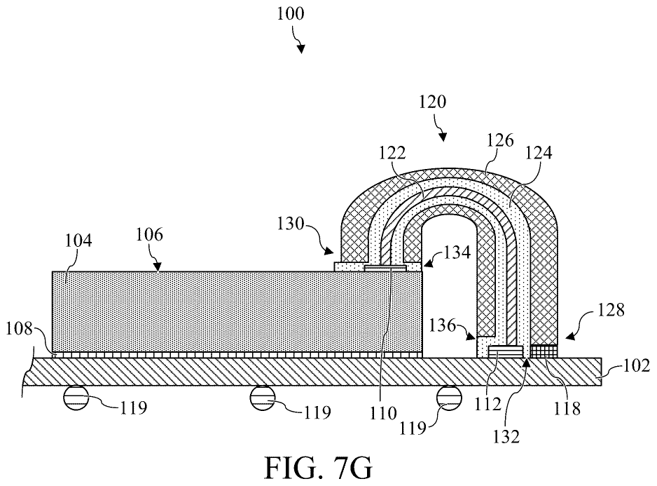

FIG. 7A-FIG. 7G show various processes for creating semiconductor package 100 (see, FIG. 7G). More specifically, FIG. 7A-FIG. 7G show cross-sectional front views of semiconductor components or parts undergoing processes P1-P7 for creating semiconductor package 100 including coaxial wire assembly 120, as shown and discussed herein with respect to FIG. 6. The non-limiting example shown in FIG. 7A-FIG. 7G depicts a section of semiconductor package 100 that includes coaxial wire assembly 120 (see e.g., FIG. 7G) extending from top surface 106 of die 104 to contact pad 112 of substrate 102. It is understood that similarly numbered and/or named components may function in a substantially similar fashion. Redundant explanation of these components has been omitted for clarity and/or brevity.

FIG. 7A shows a cross-sectional front view of die 104 being disposed over substrate 102. More specifically, die 104 is disposed over, position on, and/or formed above substrate 102. As shown, die 104 includes top surface 106 is uncovered and/or exposed in FIG. 7A. As discussed herein, die 104 includes at least one die contact pad 110 formed directly in and/or directly on the exposed top surface 106. Substrate 102 also includes contact pad 112 formed therein and/or thereon, as well as ground pad 118 formed therein and/or thereon, directly adjacent contact pad 112—opposite die 104. FIG. 7A corresponds to process P1 shown in FIG. 6.

FIG. 7B shows bond wire 122 connected to die 104 and substrate 102. More specifically, bond wire 122 is connected, contacts, and/or electrically/communicatively coupled to die contact pad 110 formed in/on top surface 106 of die 104 and contact pad 112 formed in and/or on substrate 102. FIG. 7B corresponds to process P2 shown in FIG. 6.

FIG. 7C shows the ground pad 118 of the substrate masked. That is, a masking material 150 is disposed directly over and/or substantially covering the upper surface of the ground pad 118. Additionally, masking material 150 (shown in phantom as optional) is also disposed directly over and/or substantially covers at least a portion of top surface 106 of die 104. In the non-limiting example, the masking material formed over the top surface of die 104 is formed adjacent to and/or does not cover die contact pad 110. FIG. 7C corresponds to process P3 shown in FIG. 6.

FIG. 7D shows dielectric material 124 disposed over bond wire 120. More specifically, dielectric material 124 is disposed over, substantially covers, and/or surrounds bond wire 120 extending between die contact pad 110 and contact pad 112. Additionally in the non-limiting example where masking material is not disposed over top surface 106 of die 104, dielectric material 124 substantially covers top surface 106 of die 104 when disposed over bond wire 120. Furthermore, disposing dielectric material 124 over bond wire 120, also includes disposing and/or forming a portion of dielectric material between contact pad 112 and ground pad 118 of substrate 102, opposite die 104. FIG. 7D corresponds to process P4 shown in FIG. 6.

FIG. 7E shows ground pad 118 of substrate 102 exposed. That is, and subsequent to the disposing of dielectric material 124 over bond wire 120, masking material 150 is removed from ground pad 118 to expose the upper surface of the ground pad 118. FIG. 7E corresponds to process P5 shown in FIG. 6.

FIG. 7F shows ground material 126 disposed over dielectric material 124. More specifically, ground material 126 is disposed over, covers, and/or substantially surrounds dielectric material 124 surrounding bond wire 122. Disposing ground material 126 over dielectric material 124 also includes forming ground material 126 over ground pad 118 of substrate 102. That is, the disposing of ground material 126 forms a portion or end of ground material 126 over ground pad 118 such that ground material 126 directly contacts, is disposed over, and/or substantially covers ground pad 118 formed in and/or on substrate 102. Additionally, and as discussed herein, the disposing of the ground material, as shown in FIG. 7F, includes ends of ground material 126 disposed over first extended portion 134 and second extended portion 136, respectively, of dielectric material 124. First extended portion 134 is disposed between top surface 106/die contact pad 110 of die 104 and an end of ground material 126, while second extended portion 134 is disposed between contact pad 112/substrate 102 and a distinct end of ground material 126. The disposing of ground material 126 in turn forms coaxial wire assembly 120 in semiconductor package 100. FIG. 7F corresponds to process P6 shown in FIG. 6.

FIG. 7G shows at least a portion of segment of dielectric material 124 removed to expose at least a portion of top surface 106 of die 104. That is, a segment of dielectric material 124 of coaxial wire assembly 100 is removed in order to expose a portion of top surface 106 of die 104. The segment of dielectric material 124 removed from top surface 106 also defines and/or forms first extended portion of dielectric material 124. FIG. 7G corresponds to process P7 shown in FIG. 6.

FIG. 8A-FIG. 8D show additional, non-limiting example processes for creating semiconductor package 100 (see, FIG. 8D). More specifically, FIG. 8A-FIG. 8D show cross-sectional front views of semiconductor components or parts undergoing processes for creating semiconductor package 100 including coaxial wire assembly 120—similar to those discussed herein with respect to FIG. 6. It is understood that similarly numbered and/or named components may function in a substantially similar fashion. Redundant explanation of these components has been omitted for clarity and/or brevity.

In FIG. 8A, both ground pad 118 of the substrate 102 and at least a portion of top surface 106 of die 104 is masked. That is, a masking material 150 is disposed directly over and/or substantially covering the upper surface of the ground pad 118. Additionally, masking material 150 is also disposed directly over and/or substantially covers at least a portion of top surface 106 of die 104. In the non-limiting example, the masking material formed over the top surface of die 104 is formed adjacent to and/or does not cover die contact pad 110. FIG. 8A corresponds to process P3 shown in FIG. 6.

In FIG. 8B shows dielectric material 124 disposed over bond wire 120. More specifically, dielectric material 124 is disposed over, substantially covers, and/or surrounds bond wire 120 extending between die contact pad 110 and contact pad 112. Additionally in the non-limiting example where masking material is disposed over top surface 106 of die 104, dielectric material 124 covers the portion of top surface 106 and die contact pad 110 of die 104 that is not masked by masking material 150 when disposed over bond wire 120. Furthermore, disposing dielectric material 124 over bond wire 120, also includes disposing and/or forming a portion of dielectric material between contact pad 112 and ground pad 118 of substrate 102, opposite die 104. FIG. 8B corresponds to process P4 shown in FIG. 6.

FIG. 8C shows ground pad 118 of substrate 102 and a portion of top surface 106 of die 104 exposed. That is, and subsequent to the disposing of dielectric material 124 over bond wire 120, masking material 150 is removed from ground pad 118 to expose the upper surface of the ground pad 118. Additionally, masking material 150 is removed from the portion of top surface 106 of die 104 to expose top surface 106 uncovered by dielectric material 124. FIG. 8C corresponds to process P5 and process P7 shown in FIG. 6.

FIG. 8D shows ground material 126 disposed over dielectric material 124. More specifically, ground material 126 is disposed over, covers, and/or substantially surrounds dielectric material 124 surrounding bond wire 122. Disposing ground material 126 over dielectric material 124 also includes forming ground material 126 over ground pad 118 of substrate 102. That is, the disposing of ground material 126 forms a portion or end of ground material 126 over ground pad 118 such that ground material 126 directly contacts, is disposed over, and/or substantially covers ground pad 118 formed in and/or on substrate 102. Additionally, and as discussed herein, the disposing of ground material 126, as shown in FIG. 8D, includes ends of ground material 126 disposed over first extended portion 134 and second extended portion 136, respectively, of dielectric material 124. First extended portion 134 is disposed between top surface 106/die contact pad 110 of die 104 and an end of ground material 126, while second extended portion 134 is disposed between contact pad 112/substrate 102 and a distinct end of ground material 126. The disposing of ground material 126 in turn forms coaxial wire assembly 120 in semiconductor package 100. FIG. 8D corresponds to process P6 shown in FIG. 6.

Based on the above, examples of the present disclosure describe a semiconductor package, comprising: a substrate; a contact pad formed on the substrate; a ground pad formed on the substrate, adjacent the contact pad; a die positioned over the substrate, adjacent the contact pad, the die including: a top surface, and a die contact pad formed on the top surface; and a coaxial wire assembly extending between the contact pad and the die contact pad of the die, the coaxial wire assembly including: a bond wire contacting and extending between the contact pad and the die contact pad; a dielectric material surrounding the bond wire; and a ground material surrounding the dielectric material. In an example, the ground material of the coaxial wire assembly contacts the ground pad formed in the substrate. In an example, a region of the dielectric material of the coaxial wire assembly is disposed between the contact pad formed on the substrate and the ground pad formed on the substrate. In an example, the dielectric material of the coaxial wire assembly further includes: an extended portion disposed directly over at least a portion of the top surface of the die, the extended portion surrounding the bond wire. In an example, the extended portion of the dielectric material is disposed between the top surface of the die and an end of the ground material. In an example, the semiconductor package further comprises a distinct die disposed over at least a portion of the top surface of the die, the distinct die including: a distinct top surface, and a distinct die contact pad formed on the distinct top surface. In an example, the semiconductor package further comprises a distinct coaxial wire assembly extending between the die contact pad of the die and the distinct die contact pad of the distinct die, the distinct coaxial wire assembly including: a distinct bond wire contacting and extending between the die contact pad and the distinct die contact pad. In an example, the dielectric material surrounds the distinct bond wire; and the ground material is disposed around the dielectric material and the distinct bond wire. In an example, the bond wire of the coaxial wire assembly includes a thickness between approximately 5 microns (μm) and approximately 20 μm.

Examples also describe a coaxial wire assembly extending between a contact pad of a substrate and a die contact pad of a die included in a semiconductor package. The coaxial wire assembly comprising: a bond wire contacting and extending between the contact pad and the die contact pad; a dielectric material layer surrounding the bond wire; and a ground material layer surrounding the dielectric material layer. In an example, the dielectric material layer further includes: a first extended portion surrounding the bond wire, adjacent the die contact pad of the die, the first extended portion disposed directly over at least a portion of the die contact pad of the die; and a second extended portion surrounding the bond wire, adjacent the contact pad of the substrate, the second extended portion disposed directly over at least a portion of the contact pad of the substrate, adjacent the die. In an example, the ground material layer is disposed over the first extended portion of the dielectric material layer and the second extended portion of the dielectric material layer. In an example, the bond is formed from an electrically conductive material selected from the group consisting of: gold (Au), copper (Cu), silver (Ag), aluminum (Al), palladium (Pd), platinum (Pt), nickel (Ni), silicon carbide (SiC), silver alloy, and gold alloy. In an example, the dielectric material layer is formed from an insulative material selected from the group consisting of: silicon dioxide, silicon nitride, aluminum oxide, high-k dielectrics, low-k dielectrics, organic dielectrics, glass, acrylic, polyurethane, epoxy, and polymers. In an example, the ground material layer is formed from an electrically conductive material selected from the group consisting of: copper (Cu), silver (Ag), gold (Au), aluminum (Al), and metal alloys. In an example, the bond wire includes a thickness between approximately 5 microns (μm) and approximately 20 μm.

Examples also describe a semiconductor package, comprising: a substrate including: a first contact means; and a ground means formed adjacent the first contact means; a die positioned over the substrate, adjacent the first contact means, the die including: a top surface, and a second contact mean formed on the top surface; and a coaxial wire assembly extending between the first contact means and the second contact means, the coaxial wire assembly including: an electrical bonding means contacting and extending between the first contact means and the second contact means; an insulative means surrounding the electrical bonding means; and a conductive means surrounding the insulative means. In an example, the conductive means of the coaxial wire assembly contacts the ground means of the substrate. In an example, the insulative means of the coaxial wire assembly is disposed between the first contact means of the substrate and the ground means of the substrate. In an example, an extended portion of the insulative means is disposed between the top surface of the die and the conductive means.

The foregoing drawings show some of the processing associated according to several embodiments of this disclosure. In this regard, each drawing or block within a flow diagram of the drawings represents a process associated with embodiments of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A semiconductor package, comprising:
a substrate;
a contact pad formed on the substrate;
a ground pad formed on the substrate, adjacent the contact pad;
a die positioned over the substrate, adjacent the contact pad, the die including:
a top surface; and
a die contact pad formed on the top surface; and
a coaxial wire assembly extending between the contact pad and the die contact pad of the die, the coaxial wire assembly including:
a bond wire contacting and extending between the contact pad and the die contact pad;
a dielectric material surrounding the bond wire; and
a ground material surrounding the dielectric material.

2. The semiconductor package of claim 1, wherein the ground material of the coaxial wire assembly contacts the ground pad formed on the substrate.

3. The semiconductor package of claim 1, wherein a region of the dielectric material of the coaxial wire assembly is disposed between the contact pad formed on the substrate and the ground pad formed on the substrate.

4. The semiconductor package of claim 1, wherein the dielectric material of the coaxial wire assembly further includes:
an extended portion disposed directly over at least a portion of the top surface of the die, the extended portion surrounding the bond wire.

5. The semiconductor package of claim 4, wherein the extended portion of the dielectric material is disposed between the top surface of the die and an end of the ground material.

6. The semiconductor package of claim 1, further comprising a distinct die disposed over at least a portion of the top surface of the die, the distinct die including:
a distinct top surface, and a distinct die contact pad formed on the distinct top surface.

7. The semiconductor package of claim 6, further comprising a distinct coaxial wire assembly extending between the die contact pad of the die and the distinct die contact pad of the distinct die, the distinct coaxial wire assembly including:
a distinct bond wire contacting and extending between the die contact pad and the distinct die contact pad.

8. The semiconductor package of claim 7, wherein:
the dielectric material surrounds the distinct bond wire; and
the ground material is disposed around the dielectric material and the distinct bond wire.

9. The semiconductor package of claim 1, wherein the bond wire of the coaxial wire assembly includes a thickness between approximately 5 microns (μm) and approximately 20 μm.

10. A coaxial wire assembly extending between a contact pad of a substrate and a die contact pad of a die included in a semiconductor package, the coaxial wire assembly comprising:
a bond wire contacting and extending between the contact pad and the die contact pad;
a dielectric material layer surrounding the bond wire; and
a ground material layer surrounding the dielectric material layer.

11. The coaxial wire assembly of claim 10, wherein the dielectric material layer further includes:
a first extended portion surrounding the bond wire, adjacent the die contact pad of the die, the first extended portion disposed directly over at least a portion of the die contact pad of the die; and
a second extended portion surrounding the bond wire, adjacent the contact pad of the substrate, the second extended portion disposed directly over at least a portion of the contact pad of the substrate, adjacent the die.

12. The coaxial wire assembly of claim 11, wherein the ground material layer is disposed over the first extended portion of the dielectric material layer and the second extended portion of the dielectric material layer.

13. The coaxial wire assembly of claim 10, wherein the bond wire is formed from an electrically conductive material selected from the group consisting of: gold (Au), copper (Cu), silver (Ag), aluminum (Al), palladium (Pd), platinum (Pt), nickel (Ni), silicon carbide (SiC), silver alloy, and gold alloy.

14. The coaxial wire assembly of claim 10, wherein the dielectric material layer is formed from an insulative material selected from the group consisting of: silicon dioxide, silicon nitride, aluminum oxide, high-k dielectrics, low-k dielectrics, organic dielectrics, glass, acrylic, polyurethane, epoxy, and polymers.

15. The coaxial wire assembly of claim 10, wherein the ground material layer is formed from an electrically conductive material selected from the group consisting of: copper (Cu), silver (Ag), gold (Au), aluminum (Al), and metal alloys.

16. The coaxial wire assembly of claim 10, wherein the bond wire includes a thickness between approximately 5 microns (μm) and approximately 20 μm.

17. A semiconductor package, comprising:
a substrate, including:
a first contact means; and
a ground means formed adjacent the first contact means;
a die positioned over the substrate, adjacent the first contact means, the die including:
a top surface; and
a second contact mean formed on the top surface; and
a coaxial wire assembly extending between the first contact means and the second contact means, the coaxial wire assembly including:
an electrical bonding means contacting and extending between the first contact means and the second contact means;
an insulative means surrounding the electrical bonding means; and
a conductive means surrounding the insulative means.

18. The semiconductor package of claim 17, wherein the conductive means of the coaxial wire assembly contacts the ground means of the substrate.

19. The semiconductor package of claim 17, wherein the insulative means of the coaxial wire assembly is disposed between the first contact means of the substrate and the ground means of the substrate.

20. The semiconductor package of claim 17, an extended portion of the insulative means is disposed between the top surface of the die and the conductive means.
